(19) United States
(12) Patent Application Publication
(10) Pub. No.: US 2013/0333754 A1
(43) Pub. Date: Dec. 19, 2013

(54) SOLAR CELL DEVICE AND PROCESS OF MANUFACTURING SAME

(71) Applicant: Naoya Itou, Ise-shi (JP)

(72) Inventor: Naoya Itou, Ise-shi (JP)

(73) Assignee: KYOCERA CORPORATION, Kyoto-shi, Kyoto (JP)

(21) Appl. No.: 14/002,047

(22) PCT Filed: Feb. 28, 2012
(86) PCT No.: PCT/JP2012/054959

§ 371 Date: Aug. 28, 2013

(30) Foreign Application Priority Data
Feb. 28, 2011 (JP) 2011-041122

(51) Int. Cl. H01L 31/0203

(52) U.S. Cl. CPC H01L 31/0203
USPC 136/256; 438/64

(57) ABSTRACT

A solar cell device and methods for manufacturing the solar cell device are disclosed. The solar cell device includes a translucent base; a solar cell element on the translucent base; a wiring conductive body on the solar cell element; and a sealing member on the wiring conductive body. The sealing member includes an ethylene-vinyl acetate copolymer; and an acid acceptor that is eccentrically located in the sealing member.

### FIELD OF ART

The present invention relates to a solar cell device, such as a solar cell module, including a sealing member containing an ethylene-vinyl acetate copolymer (hereinafter referred to as EVA (ethylene-vinyl acetate)) and at least one solar cell element, and to a method for manufacturing thereof.

### BACKGROUND ART

A solar cell module is manufactured, for example, by stacking a transparent protective member, a first EVA film, a plurality of solar cell elements electrically connected to each other by a wiring conductive body, a second EVA film, and a back sheet in this order from a light-receiving surface side and then heating and melting the first EVA film and the second EVA film to cure the first EVA film and the second EVA film by cross-linking, thereby combining the constituents into a single unit.

An EVA film containing vinyl acetate as a component, however, tends to hydrolyze to form acetic acid over time because of moisture and water permeation at a high temperature. It is evident that acetic acid may come into contact with a wiring conductive body and an electrode in a solar cell module and accelerate the formation of rust on the wiring conductive body and the electrode. For electrodes formed of a transparent electrically conductive film, acetic acid may increase the resistance of the transparent electrically conductive film.

Thus, an EVA film containing a substance that can prevent the formation of acetic acid has been proposed as a transparent film used as a sealing member of a solar cell module. This EVA film can prevent the formation of acetic acid and improve the durability of the solar cell (see, for example, Japanese Unexamined Patent Application Publication No. 2005-29588).

### SUMMARY OF THE INVENTION

### Problem to be Solved by the Invention

In addition, an increase in the additive content of an EVA film used as a sealing member in order to enhance the effect of preventing rusting in a solar cell module may result in a decrease in transparency of the sealing member and impair the power generation performance of the solar cell.

On the other hand, there is a demand for a solar cell module that can maintain its good power generation performance for a long time even in a severe outdoor environment.

Accordingly, it is a principal object of the present invention to provide a solar cell device that can prevent rusting of metal components, such as wiring conductive bodies and solar cell element electrodes, formed in the solar cell device, such as a solar cell module, have improved durability, and maintain its power generation performance, and a method for manufacturing thereof.

### Means for Solving the Problem

In a solar cell device according to an embodiment of the present invention, a solar cell element, a wiring conductive body, and a sealing member containing an ethylene-vinyl acetate copolymer and an eccentrically located acid acceptor, are sequentially stacked on a translucent base.

A method for manufacturing a solar cell device according to an embodiment of the present invention is a method for manufacturing a solar cell device in which a translucent base, a solar cell element, a wiring conductive body, and a sealing member containing an ethylene-vinyl acetate copolymer and an acid acceptor that is eccentrically located on a wiring conductive body side are sequentially stacked, and the method includes providing the solar cell element, on which the wiring conductive body is disposed, on the translucent base, applying the acid acceptor to the wiring conductive body, then, covering the solar cell element and the wiring conductive body with a resin body containing the ethylene-vinyl acetate copolymer, and heating the resin body to form the sealing member which contains the ethylene-vinyl acetate copolymer, and in which the acid acceptor that is eccentrically located on a wiring conductive body side.

A method for manufacturing a solar cell device according to an embodiment of the present invention is a method for manufacturing a solar cell device in which a translucent base, a solar cell element, a wiring conductive body, and a sealing member containing an ethylene-vinyl acetate copolymer and an acid acceptor that is eccentrically located on a wiring conductive body side, are sequentially stacked, and the method includes providing on the translucent base the solar cell element on which the wiring conductive body which comprises the acid acceptor on a surface thereof, is disposed on the solar cell element; then, covering the solar cell element and the wiring conductive body with a resin body containing the ethylene-vinyl acetate copolymer; and heating the resin body to form the sealing member which contains the ethylene-vinyl acetate copolymer, and in which the acid acceptor that is eccentrically located on the wiring conductive body side.

A method for manufacturing a solar cell device according to an embodiment of the present invention is a method for manufacturing a solar cell device in which a translucent base, a solar cell element, a wiring conductive body, a sealing member containing an ethylene-vinyl acetate copolymer and an acid acceptor that is eccentrically located on a wiring conductive body side, and a protective member are sequentially stacked, and the method includes sequentially stacking a resin body containing the ethylene-vinyl acetate copolymer, and the acid acceptor on the protective member; providing on the acid acceptor the solar cell element on which the wiring conductive body is disposed, such that an acid acceptor side is disposed at the wiring conductive body side; providing on the solar cell element the translucent base, and then, heating the resin body to form the sealing member that contains the ethylene-vinyl acetate copolymer, and in which the acid acceptor is eccentrically located on the wiring conductive body side.

A method for manufacturing a solar cell device according to an embodiment of the present invention is a method for manufacturing a solar cell device in which a translucent base, a solar cell element, a wiring conductive body, a sealing member containing an ethylene-vinyl acetate copolymer and an acid acceptor that is eccentrically located on a wiring conductive body side, and a protective member are sequentially stacked, and the method includes sequentially stacking, on the protective member, a resin body containing the ethylene-vinyl acetate copolymer, and the solar cell element on which the wiring conductive body on a surface of which the acid acceptor is formed is disposed, such that the resin body is in contact with the acid acceptor; providing the translucent base on the solar cell element, and heating the resin body to form the sealing member which contains the ethylene-vinyl acetate copolymer, and in which the acid acceptor that is eccentrically located on the wiring conductive body side.

A method for manufacturing a solar cell device according to an embodiment of the present invention is a method for manufacturing a solar cell device in which a solar cell element, a wiring conductive body, and a sealing member which contains an ethylene-vinyl acetate copolymer, and in which an acid acceptor is eccentrically located in a layer in a center portion of the sealing member in the thickness direction, are sequentially stacked on a translucent base, and the method includes stacking sequentially on the translucent base the solar cell element on which the wiring conductive body is disposed, a first resin body containing the ethylene-vinyl acetate copolymer, the acid acceptor layer, and a second resin body containing the ethylene-vinyl acetate copolymer; and then, heating the first resin body and the second resin body to form the sealing member containing the ethylene-vinyl acetate copolymer and the acid acceptor that is eccentrically located in a layer in the center portion of the sealing member in the thickness direction.

### Effect of the Invention

According to the solar cell device and the methods for manufacturing the solar cell device, the sealing member contains no additive that reduces transparency and therefore, the sealing member can maintain high transparency. Owing to the effects of an acid acceptor that can trap and neutralize acetic acid, even when acetic acid is produced from the sealing member, the acid acceptor can prevent acetic acid from acting on wiring conductive bodies and prevent rusting of the wiring conductive bodies and electrodes, and thus, a solar cell device having improved durability can be provided without impairing the power generation performance of the solar cell device.

### BRIEF DESCRIPTION OF THE DRAWINGS

FIG. 1 is a schematic plan view of two solar cell elements connected in series in a solar cell device according to an embodiment of the present invention.

FIG. 2 is a schematic plan view of solar cell elements connected to each other inside a solar cell device according to an embodiment of the present invention.

FIG. 3 is a schematic exploded cross-sectional view of a partial structure of a solar cell device according to an embodiment of the present invention.

FIG. 4 is a schematic plan view of a structure of a solar cell device according to one embodiment of the present invention.

FIGS. 5 (a) to (e) are cross-sectional views schematically showing a method for manufacturing a solar cell device according to an embodiment of the present invention.

FIGS. 6 (a) to (e) are cross-sectional views schematically showing a method for manufacturing a solar cell device according to an embodiment of the present invention.

FIGS. 7 (a) to (e) are cross-sectional views schematically showing a method for manufacturing a solar cell device according to an embodiment of the present invention.

FIGS. 8 (a) to (e) are cross-sectional views schematically showing a method for manufacturing a solar cell device according to an embodiment of the present invention.

FIGS. 9 (a) to (e) are cross-sectional views schematically showing a method for manufacturing a solar cell device according to an embodiment of the present invention.

FIG. 10 is a cross-sectional view of a sealing member constituting a solar cell device, schematically illustrating distribution of an acid acceptor in the sealing member according to one embodiment of the present invention.

### EMBODIMENTS FOR CARRYING OUT THE INVENTION

A solar cell device and methods for manufacturing the solar cell device according to an embodiment of the present invention (hereinafter referred to as the present embodiment) will be described in detail below with reference to the accompanying drawings. Like parts are designated by like reference numerals throughout these figures and will not be described again. These figures are schematic views and do not necessarily reflect the actual sizes and positional relationship.

### <Connection of Plurality of Solar Cell Elements>

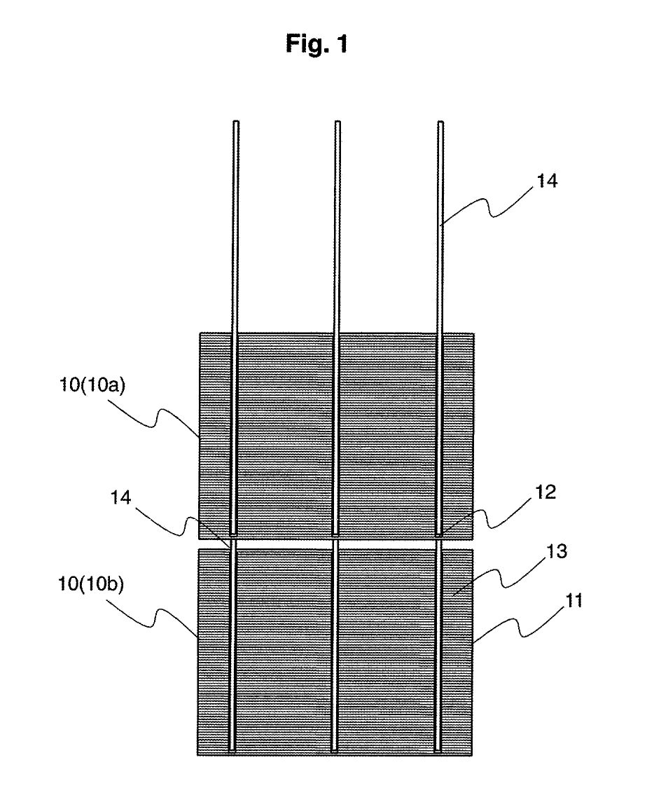

First, connection of a plurality of solar cell elements that constitute a solar cell device will be described below. For the sake of simplicity, FIG. 1 illustrates two solar cell elements 10a and 10b connected in series by wiring conductive bodies 14, which are metallic conductors.

Each of the solar cell elements 10a and 10b includes a semiconductor substrate 11, for example, composed of rectangular single-crystal silicon or polycrystalline silicon having a thickness in the range of approximately 0.3 to 0.4 mm and approximately 156 mm square in a plan view. Electrodes are disposed on a surface of the semiconductor substrate. The semiconductor substrate 11 includes a pn junction in which a p layer containing a large amount of p-type impurity, such as boron, and an n layer containing a large amount of n-type impurity, such as phosphorus are in contact with each other.

For example, bus bar electrodes 12 and finger electrodes 13 which are perpendicular to the bus bar electrodes 12 are disposed on surfaces of the solar cell elements 10. These electrodes are, for example, in which a silver paste mainly composed of silver by a screen printing method is applied and fired. The surfaces of the bus bar electrodes 12 are substantially entirely coated with solder so as to protect the bus bar electrodes 12 and facilitate the mounting of the wiring conductive bodies 14. Also, each of the finger electrodes 13 has a width in the range of approximately 0.1 to 0.2 mm and is parallel to a side of the periphery of the solar cell elements 10. Many finger electrodes 13 are formed to efficiently collect photogenerated carriers. In addition, the bus bar electrodes 12 receive the collected carriers and have a width of approximately 2 mm for the mounting of the wiring conductive bodies 14, and two or more, preferably three or four, bus bar electrodes 12 are formed substantially perpendicularly to the finger electrodes 13. The bus bar electrodes 12 and the finger electrodes 13 are also provided on the back sides (non-light-receiving surfaces) of the solar cell elements 10.

The wiring conductive bodies 14 are made of an electrically conductive metal, such as silver, copper, aluminum, or iron, preferably copper in terms of electrical conductivity and ease of soldering. The wiring conductive bodies 14 are entirely coated with eutectic solder, for example. This solder coat is performed by immersing copper foil in a solder bath, and by coating with the solder coat to have a thickness in the range of approximately 20 to 70 μm on one side. The wiring conductive bodies 14 are cut to an appropriate length.

The wiring conductive bodies 14 have a thickness in the range of approximately 0.1 to 0.5 mm and a width equal to or smaller than the width of the bus bar electrodes 12 such that the wiring conductive bodies 14 do not cast a shadow on the light-receiving surface of the solar cell elements 10a and 10b during the soldering of the solar cell elements 10a and 10b. The wiring conductive bodies 14 substantially entirely overlap with the bus bar electrodes 12 and also overlap with the bus bar electrodes (not shown) on the non-light-receiving surfaces of adjacent solar cell elements. For example, when a polycrystalline silicon solar cell element of 156 mm square is used, the wiring conductive bodies 14 have a width in the range of approximately 1 to 3 mm and a length in the range of approximately 150 to 350 mm. Note that the reason that the wiring conductive bodies 14 substantially entirely overlap with the bus bar electrodes 12 on the light-receiving surface is for reducing the resistance component.

The following is a method for connecting the solar cell elements 10a and 10b in series via the bus bar electrodes 12 and the wiring conductive bodies 14 by soldering.

First, the wiring conductive bodies 14 are placed on the bus bar electrodes 12 of the solar cell element 10a. While the wiring conductive bodies 14 are held down with pins, solder on the bus bar electrodes 12 and the wiring conductive bodies 14 on the solar cell element 10a is melted by blowing hot air or pressing a soldering iron, thereby making connection.

The other ends of the wiring conductive bodies 14 are placed on the bus bar electrodes (not shown) on the back side of the solar cell elements 10b, and solder is melted in the same manner to make connections. For the wiring conductive bodies 14 composed of copper, the distance between the solar cell elements 10a and 10b is preferably in the range of approximately 1 to 5 mm in consideration of the power generation efficiency of the solar cell module and prevention of breakage, chipping, and cracking during lamination.

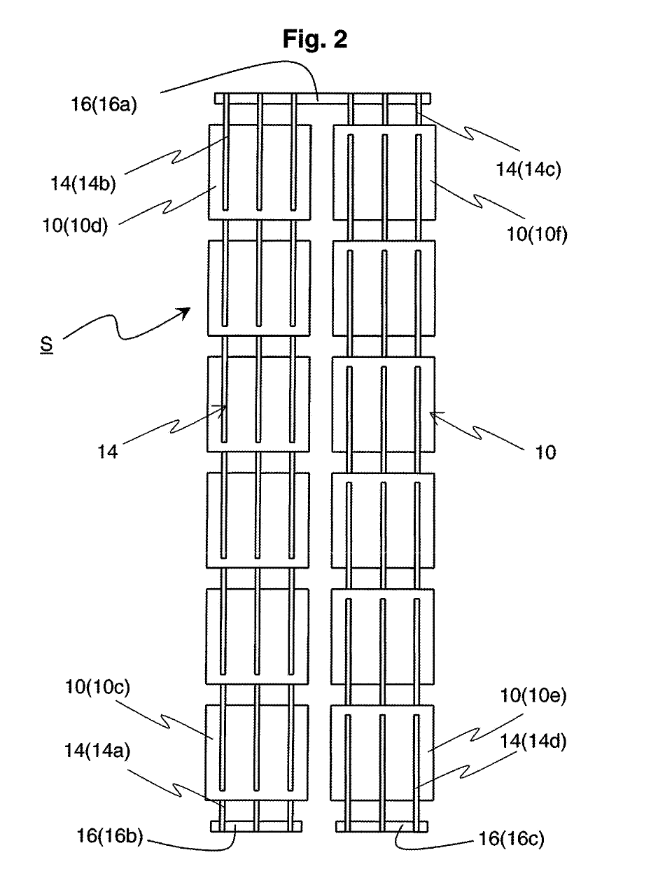

FIG. 2 illustrates an exemplary connection between solar cell elements 20 in a solar cell device S. In FIG. 2, illustrated is a structure in which two solar cell element arrays, each of which includes six solar cell elements 10 connected in series via wiring conductive bodies 14, are connected in series via connecting wires 16 (16a, 16b, 16c). The connecting wires 16 are metallic conductors made of the same material as the wiring conductive bodies 14.

Among the solar cell elements 10, specifically, the solar cell elements 10c, 10d, 10e, and 10f are terminal solar cell elements of the six solar cell elements 10 connected in line. One end of each of wiring conductive bodies 14a, 14b, 14c, and 14d is connected to the solar cell elements 10c, 10d, 10e, and 10f, respectively, and the other end is connected to the connecting wire 16a, 16b, or 16c.

The connecting wires 16 are prepared, for example, by cutting copper foil, which has a thickness in the range of approximately 0.2 to 1.0 mm and a width in the range of approximately 3 to 8 mm and is entirely coated with solder, to a predetermined length.

The connecting wire 16a connects the wiring conductive bodies 14b and 14c connected to the two adjacent solar cell elements 10d and 10f by soldering. The connecting wire 16a has a length substantially equal to the total of the length of the two solar cell elements 10d and 10e and the distance between the solar cell elements.

The connecting wires 16b and 16c each connect three wiring conductive bodies 14a and 14d connected to the terminal solar cell element 10c and 10e in the solar cell element array to which the connecting wires 16b and 16c are connected, respectively. Each of these wiring conductive bodies has a length substantially equal to the length of the solar cell element 10c or 10e.

In the manufacture of the solar cell device S according to the present embodiment, for example, surfaces of the wiring conductive bodies 14 and the connecting wires 16 are coated with an acid acceptor, which is a substance for trapping or neutralizing acetic acid. When the surfaces of the wiring conductive bodies 14 and the connecting wires 16 are coated with the acid acceptor, it is preferable to substantially uniformly coat the entire surface of the wiring conductive bodies 14 and the connecting wires 16 with the acid acceptor.

One exemplary method for uniformly coating the surfaces of the wiring conductive bodies 14 and the connecting wires 16 with the acid acceptor includes a method in which a proper amount of acid acceptor dispersed in a solvent, such as an alcohol, is applied to the surfaces and the solvent is dried.

The acid acceptor used in the present embodiment may be a material that can trap or neutralize acetic acid even when EVA, which is used in a sealing member for sealing the solar cell elements 10, hydrolyzes to form acetic acid over time because of moisture and water permeation at a high temperature. For example, the acid acceptor may be at least one metal oxide selected from magnesium oxide, calcium oxide, and zinc oxide, at least one metal hydroxide selected from magnesium hydroxide, calcium hydroxide, and barium hydroxide, a complex metal oxide or a complex metal hydroxide thereof, or a mixture of these compounds. In particular, at least one selected from the group consisting of magnesium oxide, calcium oxide, zinc oxide, magnesium hydroxide, calcium hydroxide, and barium hydroxide may be used as the acid acceptor. At least 0.1 g of the acid acceptor per solar cell element having the size described above has a sufficient effect.

The acid acceptor may be applied to the surfaces of the wiring conductive bodies 14 and the connecting wires 16, and also may be applied to the entire back side of the solar cell elements 10, but the acid acceptor is preferably applied only to the back side of the solar cell elements 10 so as not to reduce light transmission through the light-receiving surface of the solar cell element.

### <Solar Cell Device>

The exemplary structure of the solar cell device according to the present embodiment will be mainly described below.

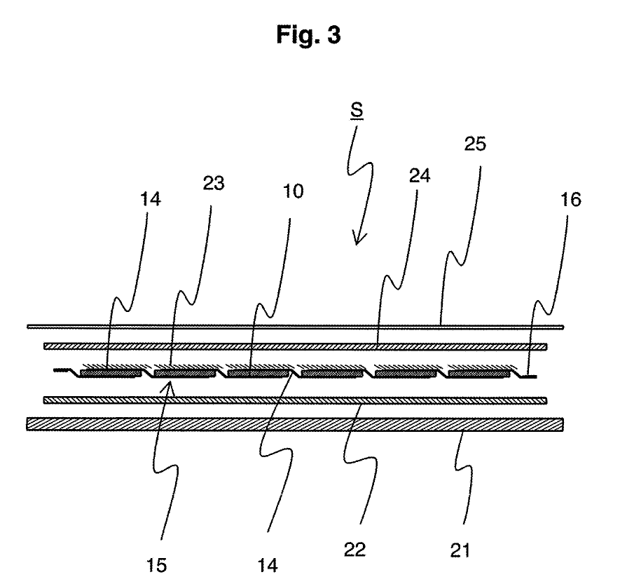

For example, as illustrated in the cross-sectional view, which is breakdown, of FIG. 3, the solar cell device S includes a structure in which the solar cell elements 10, the wiring conductive bodies 14, and a sealing member (a back-side sealing member 24) containing an eccentrically located acid acceptor 23, are stacked sequentially on a translucent base 21. Although FIG. 3 illustrates for the sake of clarity that the acid acceptor 23 is separated from the back-side sealing member 24 and is disposed on the wiring conductive bodies 14 side on the back side of the solar cell elements 10, the acid acceptor 23 is, in practice, eccentrically located on the wiring conductive bodies 14 side of the sealing member.

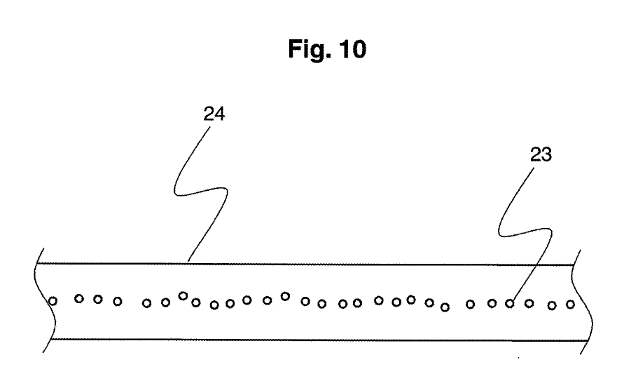

The acid acceptor 23 may be eccentrically located in a region in the sealing member, and for example, as illustrated in FIG. 10, the acid acceptor 23 may also be eccentrically located in a layer in the center portion of the back-side sealing member 24 in the thickness direction.

The structure of the solar cell device S illustrated in FIG. 3 will be described below. At least one or more solar cell elements 10, the wiring conductive bodies 14, which are metallic conductors connected to electrodes of the solar cell elements 10, a covering member containing the acid acceptor 23, and the back-side sealing member 24, which is a sealing member containing EVA, are sequentially stacked on the translucent base 21 through which light enters. In this basic structure, a member, such as a back sheet 25, which is a protective member, may be disposed on the back-side sealing member 24. A light-receiving-surface-side sealing member 22 may be disposed between the translucent base 21 and the solar cell elements 10, and the acid acceptor 23 may be disposed between the wiring conductive bodies 14 disposed between the light-receiving-surface-side sealing member 22 and the solar cell elements 10.

The solar cell device S illustrated in FIG. 3 includes a structure in which the light-receiving-surface-side sealing member 22, which is a first sealing member containing EVA, a solar cell element array 15 including a plurality of solar cell elements 10 electrically connected to each other, the wiring conductive bodies 14 connected to electrodes of the solar cell elements 10 and described above with reference to FIGS. 1 and 2, and the back-side sealing member 24 containing EVA and the acid acceptor 23 that is eccentrically located on the wiring conductive bodies 14 side, are sequentially stacked on the translucent base 21. The acid acceptor may be present in the light-receiving-surface-side sealing member 22. In this case, the amount of acid acceptor may be adjusted so as not to reduce light transmission.

A substrate made of glass or a synthetic resin, such as a polycarbonate resin is used for the translucent base 21. A white glass sheet, a tempered glass sheet, a heat strengthened glass sheet, or a heat-reflecting glass sheet, for example, a white tempered glass sheet having a thickness in the range of approximately 3 to 5 mm are used as a glass substrate. In a case in which a substrate made of a synthetic resin is used as the translucent base 21, the substrate may have a thickness of approximately 5 mm.

An EVA sheet having a thickness in the range of approximately 0.4 to 1 mm may be used for the light-receiving-surface-side sealing member 22 and the back-side sealing member 24. These are hot-pressed under reduced pressure with a laminator to be fused with other members into a single unit.

EVA may be mixed with titanium oxide, a pigment, or the like to have a white color, or the like, but when the light-receiving-surface-side sealing member 22 is colored, the amount of light that reaches the solar cell elements 10 may decrease and power generation efficiency may decrease, and therefore, EVA is preferably colorless and transparent.

EVA for use in the back-side sealing member 24 may be colorless and transparent or, depending on the installation environment of the solar cell module, may be mixed with titanium oxide, a pigment or the like, to have a white color.

As described above, for the base of the solar cell elements 10, a single-crystal silicon or polycrystalline silicon substrate having a thickness in the range of approximately 0.3 to 0.4 mm can be used, but other semiconductor materials may be used.

The wiring conductive bodies 14 and the connecting wires 16 are described above and will not be described again.

For the back sheet 25, which is a protective member, a weather-resistant fluoropolymer sheet having aluminum foil or an alumina- or silica-deposited poly(ethylene terephthalate) (PET) sheet to prevent moisture permeation may be used.

One or more slits are provided in the back sheet 25 at a predetermined position, and an output wires (not shown) is are drawn out to the surface of the back sheet 25 through the slits with a pair of tweezers before lamination.

The translucent base 21, the light-receiving-surface-side sealing member 22, the solar cell elements 10 (constituting a single solar cell element array (solar cell element string) or a plurality of solar cell element arrays in which the solar cell elements 10 are electrically connected to each other) connected to the wiring conductive bodies 14 and the connecting wires 16, the back-side sealing member 24, and the back sheet 25 are stacked. Then, these are set in a laminator and heated while pressed to form a single body under a reduced pressure in the range of approximately 50 to 150 Pa at a temperature in the range of approximately 100° C. to 200° C. for approximately 15 to 60 minutes.

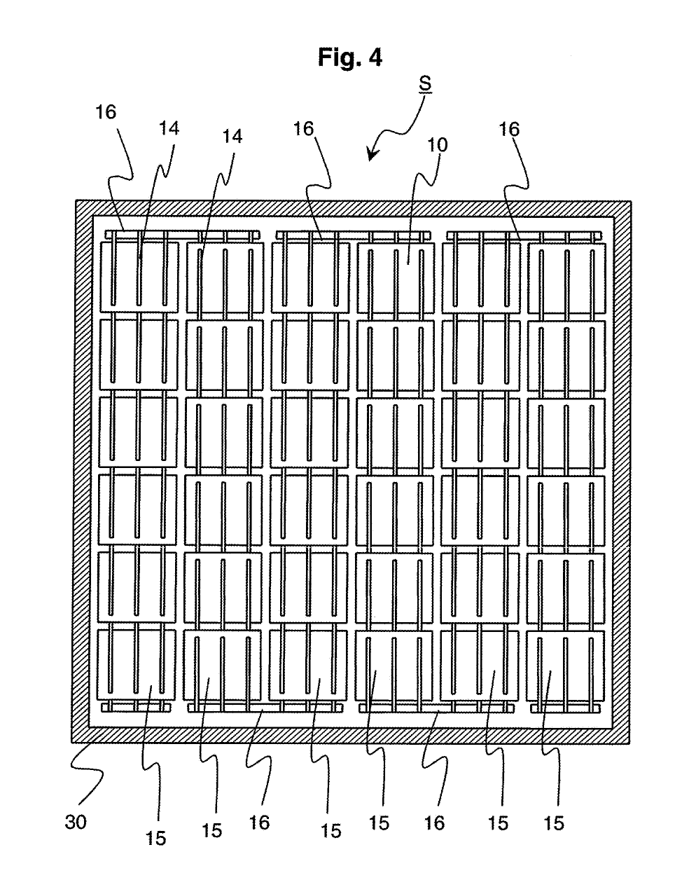

As illustrated in FIG. 4, the periphery of the single body is entirely surrounded by a frame 30 made of a metal, such as aluminum. That is, strength required for a solar cell device and the frame 30 required for the installation of the solar cell device S on a building is attached to complete the solar cell device S. A terminal box (not shown) including a cable for external circuit connection may be disposed on the back side of the solar cell device S.

### <Method for Manufacturing Solar Cell Device>

Next, in a manufacturing method according to the present embodiment, exemplary processes up to heating a sealing member will be described. For the acid acceptor 23, magnesium hydroxide particles having an average particle size of approximately 3.5 μm, for example, is used. For the other members, various materials described above can be used.

In the manufacture of the solar cell device S in which the solar cell elements 10, the wiring conductive bodies 14 that are metallic conductors, the acid acceptor 23, and the back-side sealing member 24 that is a sealing member containing EVA are sequentially stacked on the translucent base 21, a simple manufacturing method up to the heating of the sealing member includes sequentially stacking the solar cell elements 10 and the wiring conductive bodies 14 on the translucent base 21, applying the acid acceptor 23 to the wiring conductive bodies 14, thereafter, covering the solar cell elements 10 and the wiring conductive bodies 14 with the back-side sealing member 24, and heating at least the back-side sealing member 24.

In the manufacture of a solar cell device in which the solar cell elements 10, the wiring conductive bodies 14, the acid acceptor 23, and the back-side sealing member 24 containing EVA are sequentially stacked on the translucent base 21, as another simple manufacturing method up to the heating of the sealing member, a method that includes sequentially stacking the solar cell elements 10 and the wiring conductive bodies 14 to a surface of which the acid acceptor 23 has been applied, on the translucent base 21, covering the solar cell elements 10 and the wiring conductive bodies 14 with the back-side sealing member 24, and heating at least the back-side sealing member 24, may be used.

In the manufacture of the solar cell device S in which the solar cell elements 10, the wiring conductive bodies 14, the acid acceptor 23, the back-side sealing member 24 containing EVA, and the back sheet 25 that is a protective member, are sequentially stacked on the translucent base 21, a method that includes sequentially stacking the back-side sealing member 24 and the acid acceptor 23 on the back sheet 25, providing the solar cell elements 10, on which wiring conductive bodies 14 are provided, on the acid acceptor 23 such that a wiring conductive bodies 14 side is located at an acid acceptor 23 side, then, providing the translucent base 21 on the solar cell elements 10, and heating at least the back-side sealing member 24, may be used.

In the manufacture of the solar cell device S in which the solar cell elements 10, the wiring conductive bodies 14, the acid acceptor 23, the back-side sealing member 24 containing EVA, and the back sheet 25 are sequentially stacked on the translucent base 21, a method that includes sequentially stacking the back-side sealing member 24 and the solar cell elements 10, on which wiring conductive bodies 14 on a surface of which the acid acceptor 23 is provided are provided, on the back sheet 25, such that the back-side sealing member 24 is in contact with the acid acceptor 23; thereafter, providing the translucent base 21 on the solar cell elements 10; and heating at least the back-side sealing member 24, may be used.

Furthermore, in the manufacture of the solar cell device S in which the solar cell elements 10, the wiring conductive bodies 14, and a sealing member which contains EVA and in which the acid acceptor 23 is eccentrically located in a layer in the center portion of the sealing member in the thickness direction, are sequentially stacked on the translucent base 21, the solar cell elements 10 on which the wiring conductive bodies 14 are disposed, a first resin body containing EVA, an acid acceptor layer, and a second resin body containing EVA may be sequentially stacked on the translucent base 21, and then, the first resin body and the second resin body may be heated to form a sealing member which contains EVA and in which the acid acceptor 23 is eccentrically located in a layer in the center portion of the sealing member in the thickness direction.

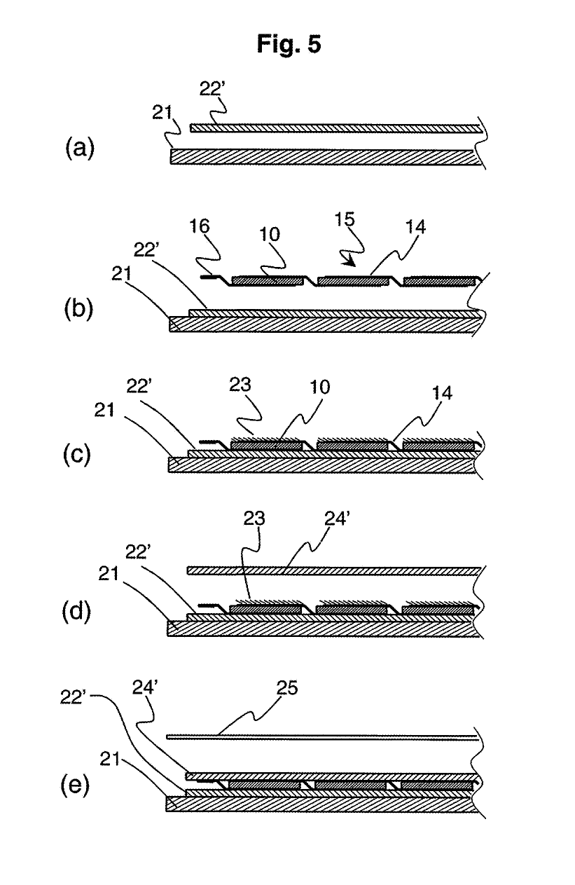

Next, a method for manufacturing the solar cell device S in which the translucent base 21, the solar cell elements 10, the wiring conductive bodies 14, and a sealing member (the back-side sealing member 24) which contains EVA and in which the acid acceptor 23 is eccentrically located on the wiring conductive bodies 14 side as illustrated in FIG. 3 will be described below with reference to FIG. 5. A solar cell sealed with a sealing member may be a single solar cell element 10 that includes the wiring conductive bodies 14 or may be at least one solar cell element array that includes a plurality of solar cell elements 10 electrically connected to each other via the wiring conductive bodies 14, or the like. In an exemplary manufacturing method described below, the solar cell sealed with a sealing member is a solar cell element array.

For example, after the following processes (A1) to (A5) are performed, the solar cell device S as illustrated in FIG. 3 is manufactured by combining all the components into a single body by hot-pressing under reduced pressure.

(A1) A light-receiving-surface-side resin body 22′, which is made of, for example, EVA, an olefin resin, or the like, to become the light-receiving-surface-side sealing member 22 after the above-mentioned hot-pressing, is placed on the translucent base 21 (see FIG. 5(a)).

(A2) One or more solar cell element arrays 15, in which a plurality of solar cell elements 10, at least on which (on the back side of the solar cell elements 10) the wiring conductive bodies 14 are disposed, electrically connected to each other are provided on the light-receiving-surface-side resin body 22′ disposed on the translucent base 21 (see FIG. 5(b)). In a case in which wiring conductive bodies are also disposed on the light-receiving surfaces of the solar cell elements 10, the wiring conductive bodies on the light-receiving surface may be coated with the acid acceptor 23 in advance.

(A3) The acid acceptor 23 is provided on at least the wiring conductive bodies 14 which are disposed on the back side of the solar cell element array 15 (see FIG. 5(c)).

(A4) A back-side resin body 24′, which contains EVA and is to become the back-side sealing member 24, is provided on the solar cell element array 15 (see FIG. 5(d)).

(A5) The back sheet 25 is provided on the back-side resin body 24′ (see FIG. 5(e)).

The entire body including the light-receiving-surface-side resin body 22′ and the back-side resin body 24′ is pressed while heated in a laminator, for example, under a reduced pressure in the range of approximately 50 to 150 Pa at a temperature in the range of approximately 100° C. to 200° C. for approximately 15 to 60 minutes, thereby making it possible to manufacture the solar cell device S illustrated in FIG. 3.

Also, in the manufacture of the solar cell device S illustrated in FIG. 3, after the solar cell elements 10, on which the wiring conductive bodies 14 on a surface of which the acid acceptor 23 is provided is disposed, is provided on the translucent base 21, covering the solar cell elements 10 and the wiring conductive bodies 14 with a resin body containing EVA, and heating the resin body to form a sealing member which contains EVA and in which the acid acceptor 23 is eccentrically located on the wiring conductive bodies 14 side.

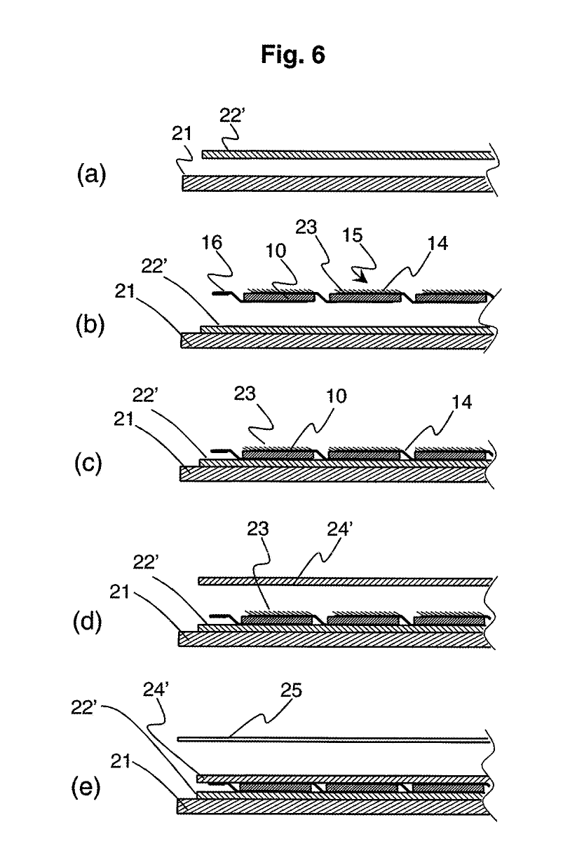

In other words, the following processes (B1) to (B5) may be performed before the light-receiving-surface-side resin body 22′ and the back-side resin body 24′ are heated as illustrated in FIG. 6(e).

(B1) The light-receiving-surface-side resin body 22′ is provided on the translucent base 21 (see FIG. 6(a)).

(B2) One or more solar cell element arrays 15, in which a plurality of solar cell elements 10 electrically connected to each other via the wiring conductive bodies 14 is provided on the light-receiving-surface-side resin body 22′. In this case, the acid acceptor 23 is provided in advance on the solar cell element array 15, that is, on at least the wiring conductive bodies 14 disposed on the back side of the solar cell elements 10 (see FIGS. 6(b) and 6(c)).

(B3) The back-side resin body 24′ is provided on the solar cell element array 15 (see FIG. 6(d)).

(B4) The back sheet 25 is provided on the back-side resin body 24′ (see FIG. 6(e)).

The entire body including the light-receiving-surface-side resin body 22′ and the back-side resin body 24′ is pressed while heated in a laminator under the conditions described above, and the solar cell device S illustrated in FIG. 3 can be manufactured.

Furthermore, in the manufacture of the solar cell device S in which the translucent base 21, the solar cell elements 10, the wiring conductive bodies 14, a sealing member containing EVA and the acid acceptor 23 that is eccentrically located on the wiring conductive bodies 14 side, and the back sheet 25 that is a protective member are sequentially stacked, a resin body containing EVA and the acid acceptor 23 are sequentially stacked on the back sheet 25, the solar cell elements 10 on which the wiring conductive bodies 14 is disposed on the acid acceptor 23 such that the wiring conductive bodies 14 side is located at an acid acceptor 23 side, thereafter, the translucent base 21 on the solar cell elements 10 is provided, and the resin body is heated, and a sealing member, which contains EVA and in which the acid acceptor 23 is eccentrically located on the wiring conductive bodies 14 side, may be formed.

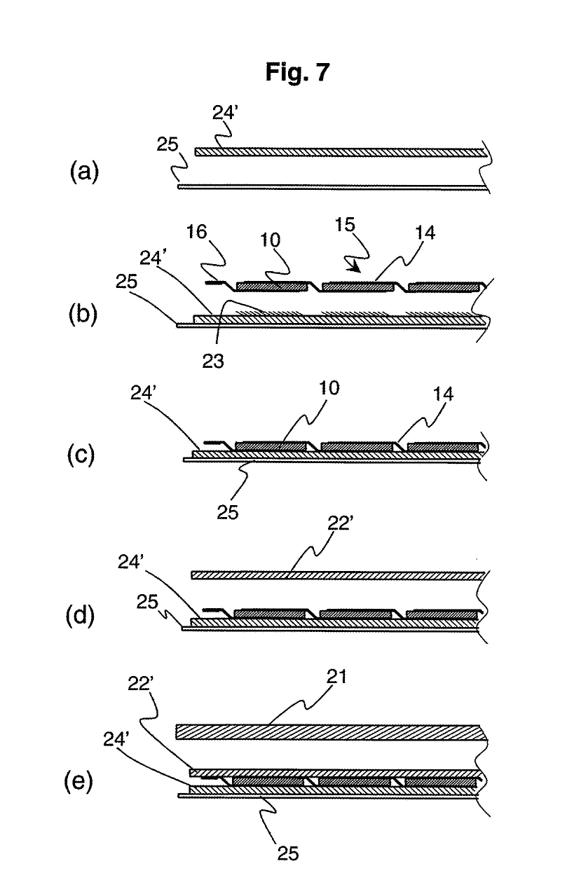

In other words, the following processes (C1) to (C5) may be performed before the light-receiving-surface-side resin body 22′ and the back-side resin body 24′ are heated as illustrated in FIG. 7(e).

(C1) The back-side resin body 24′ is provided on the back sheet 25 (see FIG. 7(a)).

(C2) The acid acceptor 23 is applied to the back-side resin body 24′ (see FIG. 7(b)).

(C3) The solar cell element array 15 in which a plurality of solar cell elements 10 are electrically connected to each other via the wiring conductive bodies 14 is provided on the back-side resin body 24′ (see FIG. 7(c)).

(C4) The light-receiving-surface-side resin body 22′ is provided on the solar cell element array 15 (see FIG. 7(d)).

(C5) The translucent base 21 is provided on the light-receiving-surface-side resin body 22′ (see FIG. 7(e)).

Then, the entire body including the light-receiving-surface-side resin body 22′ and the back-side resin body 24′ is pressed while heated in a laminator under the conditions described above, and the solar cell device S illustrated in FIG. 3 can be manufactured.

In the manufacture of the solar cell device S through the processes illustrated in FIG. 7, after a resin body containing EVA and the solar cell elements 10, on which the wiring conductive bodies 14 on a surface of which the acid acceptor 23 is provided is disposed, is sequentially stacked on the back sheet 25 such that the resin body is in contact with the acid acceptor 23, the translucent base 21 is provided on the solar cell elements 10, the resin body is heated, and a sealing member containing EVA and the acid acceptor 23 that is eccentrically located on the wiring conductive bodies 14 side may be formed.

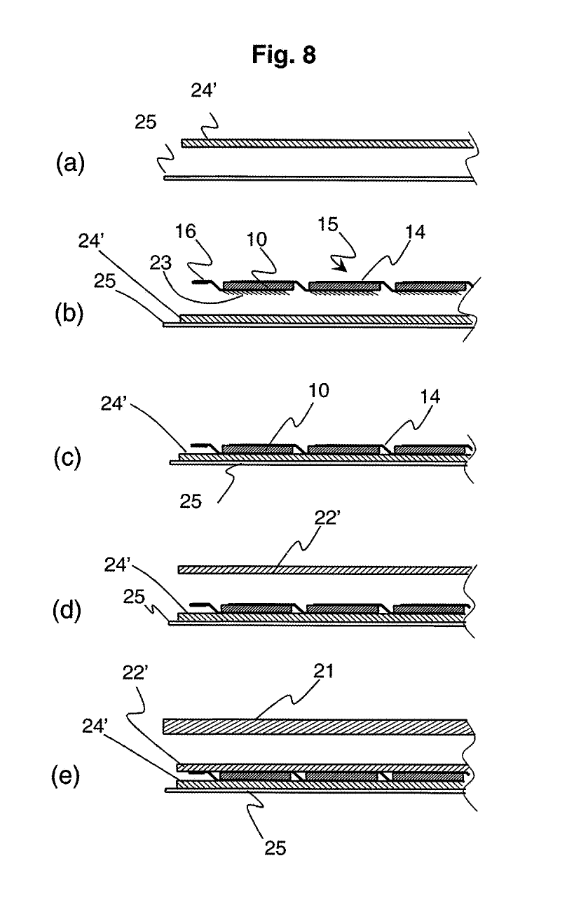

In other words, the following processes (D1) to (D5) may be performed before the light-receiving-surface-side resin body 22′ and the back-side resin body 24′ are heated as illustrated in FIG. 8(e).

(D1) The back-side resin body 24′ is provided on the back sheet 25 (see FIG. 8(a)).

(D2) The acid acceptor 23 is provided on the entire back side of the solar electronic elements 10 in the solar cell element array 15 in advance, thereby coating the wiring conductive bodies 14 with the acid acceptor 23 (see FIG. 8(b)).

(D3) The solar cell element array, which are electrically connected via the wiring conductive bodies 14 on which the acid acceptor 23 is coated in advance and the connecting wires 16, is provided on the back-side resin body 24′ (see FIG. 8(c)).

(D4) The light-receiving-surface-side resin body 22′ is provided on the solar cell element array 15 (see FIG. 8(d)).

(D5) The translucent base 21 is provided on the light-receiving-surface-side sealing member 22 (see FIG. 8(e)).

Then, the entire body including the light-receiving-surface-side resin body 22′ and the back-side resin body 24′ is pressed while heated in a laminator under the conditions described above, and the solar cell device S illustrated in FIG. 3 can be manufactured.

In addition, in the manufacture of the solar cell device S in which the solar cell elements 10, the wiring conductive bodies 14, and a sealing member which contains EVA and in which the acid acceptor 23 is eccentrically located in a layer in the center portion of the sealing member in the thickness direction, are sequentially stacked on the translucent base 21, after the solar cell elements 10 on which the wiring conductive bodies 14 are disposed, a first resin body containing EVA, an acid acceptor layer, and a second resin body containing EVA are sequentially stacked on the translucent base 21, the first resin body and the second resin body are heated, and at least the back-side sealing member 24, which contains EVA and in which the acid acceptor 23 is eccentrically located in a layer, for example, having a thickness of approximately 10 μm in the center portion of the sealing member in the thickness direction can be formed as illustrated in FIG. 10.

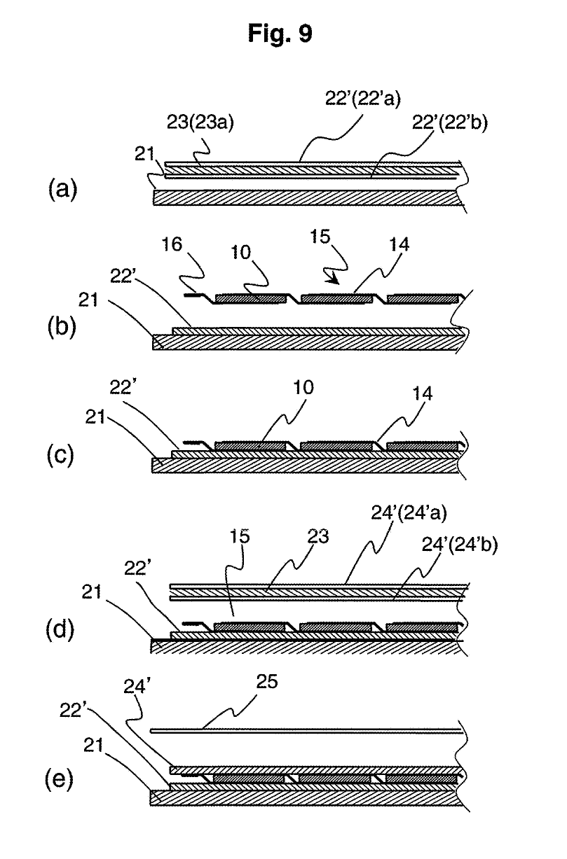

In other words, the following processes (E1) to (E5) may be performed before the light-receiving-surface-side resin body 22′ and the back-side resin body 24′ are heated as illustrated in FIG. 9(e).

(E1) The light-receiving-surface-side resin body 22′ that is composed of a first light-receiving-surface-side resin body 22′a and a second light-receiving-surface-side resin body 22′ which sandwich an acid acceptor 23a is provided on the translucent base 21 (see FIG. 9(a)).

(E2) One or more solar cell element arrays 15 in which a plurality of solar cell elements 10 are electrically connected to each other via the wiring conductive bodies 14 are provided on the light-receiving-surface-side resin body 22′ (see FIGS. 9(b) and 9(c)).

(E3) The back-side resin body 24′ that is composed of a first back-side resin body 24′a and a second back-side resin body 24′b which sandwich an acid acceptor 23b is provided on the solar cell element array 15 (see FIG. 9(d)).

(E5) The back sheet 25 is provided on the back-side resin body 24′ (see FIG. 9(e)).

Then the entire body including the light-receiving-surface-side resin body 22′ and the back-side resin body 24′ is pressed while heated in a laminator under the conditions described above, and the solar cell device S that includes a sealing member which contains EVA and in which the acid acceptor 23 is eccentrically located in a layer in the center portion of the sealing member in the thickness direction can be manufactured as illustrated in FIG. 10.

According to the solar cell device S thus completed, the light-receiving-surface-side sealing member 22 contains no additive that reduces transparency and can therefore maintain high transparency. Even when acetic acid is produced from EVA constituting the light-receiving-surface-side sealing member 22 and the back-side sealing member 24, the acid acceptor 23 can trap, neutralize the acetic acid, and so on, thereby preventing rusting of the wiring conductive bodies 14, which are metallic conductors, and electrodes. Thus, the solar cell device S having improved durability can be provided without deterioration of the power generation performance of the solar cell device S.

A back sheet is use in the present embodiment, but the amount of eccentrically located acid acceptor is adjusted in accordance with the moisture resistance of the back sheet. The amount of the acid acceptor may also be adjusted in accordance with the amount of EVA component, which affects the strength of the sealing member. The present embodiment can provide a solar cell device which easily adjusts the acid acceptor and has high durability that can prevent rusting of a wiring conductive body and an electrode even under severe conditions.

Although the present embodiment has mainly described a solar cell device that includes solar cell elements made of polycrystalline silicon connected to each other, a solar cell device according to the present invention that includes one or more solar cell element manufactured using a semiconductor material including a thin-film material other than crystal silicon, or includes a solar cell element array that includes a plurality of solar cell elements connected in parallel is also expected to have the advantages described above.

### EXAMPLES

An example of a solar cell device manufactured through the processes (E1) to (E5) and a comparative example manufactured in the same manner except that the sealing member contains no acid acceptor will be described below.

As the example, a light-receiving-surface-side resin body in which magnesium hydroxide as an acid acceptor is sandwiched between a first light-receiving-surface-side resin body made of EVA having a thickness of 0.3 mm and a second light-receiving-surface-side resin body made of EVA having a thickness of 0.3 mm was provided on a translucent base that was a white tempered glass sheet having a thickness of 3.2 mm (see FIG. 9(a)). In this case, the acid acceptor dispersed in 2-propanol was disposed between the first light-receiving-surface-side resin body and the second light-receiving-surface-side resin body. An amount of the acid acceptor was in the range of 0.2% to 0.4% by mass with respect to EVA+the acid acceptor of 100% by mass.

Then, as illustrated in FIG. 4, the solar cell, which included six solar cell element arrays each of which included six solar cell elements, each including polycrystalline silicon having a thickness of 0.2 mm and electrodes, connected in series and electrically connected to each other via wiring conductive bodies made of copper, was placed on the light-receiving-surface-side resin body (see FIGS. 9(b) and 9(c)).

Next, in the same manner as in the light-receiving surface side, an acid acceptor made of magnesium hydroxide is sandwiched between a first back-side resin body and a second back-side resin body each having the same thickness as described above was placed on the solar cell element arrays (see FIG. 9(d)). An amount of the acid acceptor was in the range of 1.4% to 2.8% by mass with respect to EVA+the acid acceptor of 100% by mass.

Next, a back sheet made of poly-ethylene terephthalate having a thickness of 0.1 mm was provided on the back-side resin body (see FIG. 9(e)).

Then, the entire body including the light-receiving-surface-side resin body and the back-side resin bodies was pressed while heated in a laminator under a reduced pressure of approximately 100 Pa at a temperature in the range of 130° C. to 160° C. for approximately 40 minutes, and the solar cell device S as illustrated in FIG. 3 was manufactured.

As for a comparative example, a solar cell device as illustrated in FIG. 3 was manufactured in the same manner as in the example except that the light-receiving-surface-side resin body and the back-side resin bodies contained no acid acceptor.

After the solar cell devices according to the example and the comparative example were left to stand in an environment, in which a temperature is 125° C., humidity is 100% RH, for 250 and 500 hours, changes in the output of the solar cell devices were measured.

As a result, in the example, deterioration of the wiring conductive bodies was not visually observed, and the solar cell device substantially maintained its initial output. In contrast, in the comparative example, rusting of the wiring conductive bodies was visually observed, and the output was not more than 90% of the initial output.

These results show that a solar cell device that includes a sealing member, which contains EVA and in which an acid acceptor is eccentrically located in a region therein, can prevent rusting of wiring conductive bodies and electrodes even in a high temperature and high humidity environment and maintain its power generation performance, without using a sealing member containing an acid acceptor in a resin body.

Although the amount of acid acceptor depends on the amount of EVA component, which affects the strength of the sealing member, it is confirmed that the present example can easily control the amount of acid acceptor and prevent rusting of wiring conductive bodies and electrodes even under severe conditions.

### DESCRIPTIONS OF THE REFERENCE NUMERALS

10 (10a, 10b, 10c, 10d, 10e): solar cell element
11: semiconductor substrate
12: bus bar electrode
13: finger electrode
14 (14a, 14b, 14c, 14d): wiring conductive body
15: solar cell element array
16 (16a, 16b, 16c): connecting wire
21: translucent base
22: light-receiving-surface-side sealing member
23: acid acceptor
24: back-side sealing member
25: back sheet (protective member)
S: solar cell device

1. A solar cell device, comprising:
a translucent base;
a solar cell element on the translucent base;
a wiring conductive body on the solar cell element; and
a sealing member on the wiring conductive body, the sealing member containing:
an ethylene-vinyl acetate copolymer; and
an acid acceptor that is eccentrically located in the sealing member.

2. The solar cell device according to claim 1, wherein the acid acceptor is mainly located in the sealing member at a side of the wiring conductive body.

3. The solar cell device according to claim 1, wherein the acid acceptor is mainly located in a layer in a center portion of the sealing member in the thickness direction.

4. The solar cell device according to claim 1, wherein the acid acceptor contains at least one selected from the group consisting of magnesium oxide, calcium oxide, zinc oxide, magnesium hydroxide, calcium hydroxide, and barium hydroxide.

5. A method for manufacturing a solar cell device which comprises an acid acceptor on a wiring conductive body therein, the method comprising:
forming a complex body comprising a translucent base, a solar cell element, and a wiring conductive body which are stacked in this order by placing the solar cell element on the translucent base such that and by placing the wiring conductive body on the solar cell element;
applying an acid acceptor onto the wiring conductive body of the complex body;
covering the solar cell element and the wiring conductive body having the acid acceptor thereon with a resin body containing the ethylene-vinyl acetate copolymer; and
heating the resin body to form the sealing member such that the acid acceptor is unevenly distributed in the sealing member.

6. A method for manufacturing a solar cell device which comprises an acid acceptor on a wiring conductive body therein, the method comprising:
preparing a complex body, the complex body comprising:
a solar cell element;
a wiring conductive body on the solar cell element; and
an acid acceptor on the wiring conductive body;
placing the complex body on a translucent base such that the translucent is closer to the solar cell element than the wiring conductive body and the acid acceptor;
covering the solar cell element and the wiring conductive body with a resin body containing the ethylene-vinyl acetate copolymer; and
heating the resin body to form the sealing member such that the acid acceptor is mainly located in the sealing member.

7. (canceled)

8. A method for manufacturing a solar cell device which comprises an acid acceptor on a wiring conductive body therein, the method comprising:
preparing a complex body, the complex body comprising:
a solar cell element;
a wiring conductive body on the solar cell element; and
an acid acceptor on the wiring conductive body;
placing a resin body containing the ethylene-vinyl acetate copolymer on a protective member;
placing the complex body on the resin body such that the resin body is in contact with the acid acceptor, placing
placing a translucent base on the complex body; and
heating the resin body to form the sealing member such that the acid acceptor is mainly located in the sealing member.

9. (canceled)

10. The method for manufacturing a solar cell device according to claim 5, wherein at least one selected from the group consisting of magnesium oxide, calcium oxide, zinc oxide, magnesium hydroxide, calcium hydroxide, and barium hydroxide is used as the acid acceptor.

11. The method according to claim 6, wherein at least one selected from the group consisting of magnesium oxide, calcium oxide, zinc oxide, magnesium hydroxide, calcium hydroxide, and barium hydroxide is used as the acid acceptor.

12. The method according to claim 8, wherein at least one selected from the group consisting of magnesium oxide, calcium oxide, zinc oxide, magnesium hydroxide, calcium hydroxide, and barium hydroxide is used as the acid acceptor.
